(19) United States
(12) Patent Application Publication
(10) Pub. No.: US 2026/0173772 A1
(43) Pub. Date: Jun. 18, 2026

(54) METHOD OF MANUFACTURING A SEMICONDUCTOR DEVICE HAVING HEXAGONAL PHASE CRYSTAL STRUCTURES

(71) Applicant: SK hynix Inc., Icheon-si (KR)

(72) Inventors: Seong Hun LEE, Icheon-si (KR); Young Jae KWON, Icheon-si (KR)

(21) Appl. No.: 19/213,477

(22) Filed: May 20, 2025

(30) Foreign Application Priority Data
Dec. 12, 2024 (KR) 10-2024-0184447

(51) Int. Cl. H10N 70/00; H10B 63/00; H10N 70/20

(52) U.S. Cl. CPC H10N 70/041; H10B 63/80; H10N 70/063; H10N 70/24; H10N 70/8265

(57) ABSTRACT

A method of manufacturing a semiconductor device includes forming a lower interconnection line; forming a lower interlayer insulating layer over the lower interconnection line; forming a lower contact plug vertically penetrating the lower interlayer insulating layer to be electrically connected to the lower interconnection line; forming a memory cell over the lower contact plug; forming a straining layer surrounding the memory cell; performing a phase change process to phase-change the straining layer into a spacer layer; forming an upper contact plug electrically connected to an upper portion of the memory cell; and forming an upper interconnection line over the upper contact plug. The spacer layer includes hexagonal phase crystal structures.

### CROSS-REFERENCE TO RELATED APPLICATION

The present application claims priority under 35 U.S. C § 119(a) to Korean Patent Application No. 10-2024-0184447, filed on Dec. 12, 2024, in the Korean Intellectual Property Office, which is incorporated herein by reference in its entirety.

### BACKGROUND

### 1. Field

The present disclosure relates to a semiconductor memory device having a spacer layer and a method of manufacturing the semiconductor memory device.

### 2. Description of the Related Art

A variable resistive semiconductor memory device have been proposed that are capable of storing data using a variable resistive layer, which can switch between different resistance states according to applied voltage or current.

### SUMMARY

An embodiment of the present disclosure is directed to a resistive semiconductor memory device having improved data retention.

An embodiment of the present disclosure is directed to a method of manufacturing a resistive semiconductor memory device having improved data retention.

In accordance with an embodiment of the present disclosure, a semiconductor device includes a lower interconnection line; a memory cell structure disposed over the lower interconnection line; and an upper interconnection line disposed over the memory cell structure. The memory cell structure includes a memory cell and a spacer layer surrounding the memory cell. The spacer layer includes hexagonal phase crystal structures.

In accordance with an embodiment of the present disclosure, a method of manufacturing a semiconductor device includes forming a lower interconnection line; forming a lower interlayer insulating layer over the lower interconnection line; forming a lower contact plug vertically penetrating the lower interlayer insulating layer to be electrically connected to the lower interconnection line; forming a memory cell over the lower contact plug, forming a straining layer surrounding the memory cell; performing a phase change process to phase-change the straining layer into a spacer layer; forming an upper contact plug electrically connected to an upper portion of the memory cell; and forming an upper interconnection line over the upper contact plug. The straining layer includes cubic phase crystal structures. The spacer layer includes hexagonal phase crystal structures.

In accordance with an embodiment of the present disclosure, a method of manufacturing a semiconductor device includes forming a switching element layer; forming a first material layer surrounding side surfaces of the switching element layer; and performing a phase change process to phase-change the first material layer into the second material layer. The first material layer includes cubic crystal structures. The second material layer includes hexagonal phase crystal structures.

### BRIEF DESCRIPTION OF THE DRAWINGS

FIGS. 1A and 1B are a circuit diagram and a perspective view schematically illustrating a semiconductor memory device according to an embodiment of the present disclosure.

FIGS. 2A to 2C are longitudinal cross-sectional views taken along line I-I′ of FIG. 1B to schematically illustrate semiconductor memory devices according to embodiments of the present disclosure.

FIGS. 3A to 3E are longitudinal cross-sectional views taken along the line I-I′ of FIG. 1B to illustrate a method of forming a memory cell structure of a semiconductor memory according to an embodiment of the present disclosure.

FIG. 4A illustrates a cubic phase crystal structure of zinc sulfide, and FIG. 4B illustrates a hexagonal phase crystal structure of zinc sulfide according to an embodiment of the present disclosure.

FIGS. 5A and 5B are longitudinal cross-sectional views taken along line I-I′ of FIG. 1B to illustrate a method of forming a memory cell structure of a semiconductor memory device according to an embodiment of the present disclosure.

FIGS. 6A and 6B are longitudinal cross-sectional views taken along line I-I′ of FIG. 1B to illustrate a method of forming a memory cell structure of a semiconductor memory device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described hereunder. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the descriptions below. All changes within the meaning and range of equivalency of the claims are included within their scope.

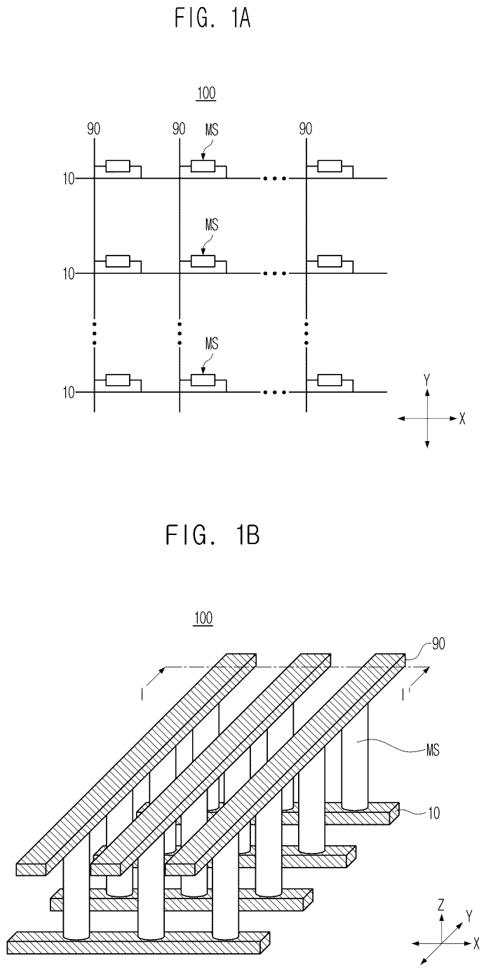

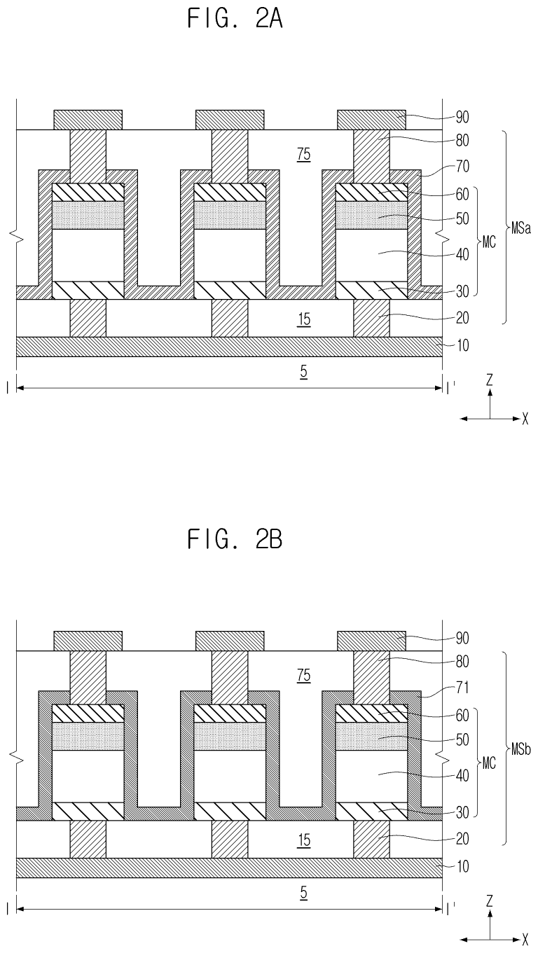

FIGS. 1A and 1B are a circuit diagram and a perspective view schematically illustrating a semiconductor memory device according to an embodiment of the present disclosure. Referring to FIGS. 1A and 1B, a semiconductor memory device 100 may include lower interconnection lines 10, upper interconnection lines 90, and memory cell structures MS. The lower interconnection lines 10 may extend parallel to each other in a first horizontal direction X. The lower interconnection lines 10 may correspond to word lines. The upper interconnection lines 90 may extend parallel to each other in a second horizontal direction Y. The upper interconnection lines 90 may correspond to bit lines. In another embodiment, the lower interconnection lines 10 may correspond to the bit lines, and the upper interconnection lines 90 may correspond to the word lines. The first horizontal direction X and the second horizontal direction Y may be perpendicular to each other. The memory cell structures MS may be disposed at intersections between the lower interconnection lines 10 and the upper interconnection lines 90, respectively, from a plan view. Each of the memory cell structures MS may have a vertical pillar shape and include a first electrode and a second electrode. First electrodes of the memory cell structures MS may be electrically connected to the lower interconnection lines 10, respectively, and second electrodes of the memory cell structures MS may be electrically connected to the upper interconnection lines 90, respectively.

FIGS. 2A to 2C are longitudinal cross-sectional views taken along line I-I′ of FIG. 1B to schematically illustrate semiconductor memory devices according to embodiments of the present disclosure. Referring to FIG. 2A, a semiconductor memory device according to an embodiment of the present disclosure may include a lower interconnection line 10 disposed over an underlying layer 5, a memory cell structure MSa over the lower interconnection line 10, and an upper interconnection line 90 over the memory cell structure MSa. The memory cell structure MSa may include a lower contact plug 20, a memory cell MC, a spacer layer 70, and an upper contact plug 80. The memory cell MC may include a lower electrode 30, a switching element layer 40, an oxygen reservoir layer 50, and an upper electrode 60.

The underlying layer 5 may include a substrate or an insulating layer disposed over the substrate. For example, the underlying layer 5 may include a silicon oxide-based insulating layer or a silicon nitride-based insulating layer disposed over the silicon substrate. The lower interconnection line 10 and the upper interconnection lines 90 may include a metal such as tungsten.

The lower interlayer insulating layer 15 may cover the lower interconnection line 10 and may surround side surfaces of the lower contact plugs 20. The lower interlayer insulating layer 15 may include an insulating layer based on silicon oxide or an insulating layer based on silicon nitride.

The lower contact plug 20 may vertically pass through the lower interlayer insulating layer 15 to electrically connect the lower interconnection line 10 to the lower electrode 30 of the memory cell MC. The lower contact plug 20 may include a metal such as tungsten or titanium, a metal nitride such as titanium nitride or aluminum nitride, or a conductor such as a metal alloy nitride such as titanium aluminum nitride.

The lower electrode 30 may be disposed over the lower contact plug 20 and the lower interlayer insulating layer 15. The lower electrode 30 may include a metal such as tungsten or titanium, or a metal nitride such as titanium nitride or aluminum nitride.

The switching element layer 40 may include a variable resistance layer. The switching element layer 40 may include a transition metal oxide layer. For example, the switching element layer 40 may include at least one of a niobium oxide (NbO) layer, a titanium oxide (TiN) layer, a hafnium oxide (HfO) layer, a zirconium oxide (ZrO) layer, a lanthanum oxide (LaO) layer, a vanadium oxide (VO) layer, a molybdenum oxide (MoO) layer, an yttrium oxide (YO), a scandium oxide (ScO) layer, a strontium oxide (SrO) layer, or a barium oxide (BaO). In one embodiment, the switching element layer 40 may include a half metal oxide layer. For example, oxygen vacancies in the switching element layer 40 may form conductive filaments through arrangements of oxygen ions.

The oxygen reservoir layer 50 may provide the oxygen ions to the switching element layer 40 or absorb the oxygen ions from the switching element layer 40. The oxygen reservoir layer 50 may include a metal oxide layer. For example, the oxygen reservoir layer 50 may include at least one of a tantalum layer, a hafnium layer, a zirconium layer, a titanium layer, a tantalum oxide layer, a hafnium oxide layer, a zirconium oxide layer, or a titanium oxide layer.

The upper electrode 60 may be disposed over the oxygen reservoir layer 50. The lower electrode 30 may include a metal such as tungsten or titanium, or a metal nitride such as titanium nitride or aluminum nitride.

The spacer layer 70 may conformally cover both sidewalls and a top surface of the memory cell MC. The spacer layer 70 may also be conformally formed over the lower interlayer insulating layer 15 exposed between the memory cells MC. The spacer layer 70 may include zinc sulfide (ZnS) having hexagonal phase crystal structures. The spacer layer 70 may further include cubic phase crystal structures. For example, some parts of the spacer layer 70 may have hexagonal phase crystal structures, and the other parts of the spacer layer 70 may have the cubic phase crystal structures. A ratio of the cubic phase crystal structures to the hexagonal phase crystal structures in the spacer layer 70 may be variously set depending on the manufacturing process.

The upper interlayer insulating layer 75 may cover the memory cells MC and the spacer layer 70, and surround side surfaces of the upper contact plugs 80. The upper interlayer insulating layer 75 may fill spaces between the memory cell structures MSa. The upper interlayer insulating layer 75 may include an insulating layer based on silicon oxide or an insulating layer based on silicon nitride.

The upper contact plug 80 may vertically pass through the upper interlayer insulating layer 75 and the spacer layer 70 to electrically connect the upper electrode 60 to the upper interconnection line 90. The upper contact plug 80 may include a conductor e.g., a metal such as tungsten or titanium, a metal nitride such as titanium nitride or aluminum nitride, or a metal alloy nitride such as titanium aluminum nitride.

Referring to FIG. 2B, a semiconductor memory device according to an embodiment of the present disclosure may include a lower interconnection line 10 over an underlying layer 5, a memory cell structure MSb over the lower interconnection line 10, and an upper interconnection line 90 over the memory cell structure MSb. The memory cell structure MSb may include a lower contact plug 20, a memory cell MC, a spacer layer 71, and an upper contact plug 80. The memory cell MC may include a lower electrode 30, a switching element layer 40, an oxygen reservoir layer 50, and an upper electrode 60.

The spacer layer 71 may include a silicon nitride layer. The spacer layer 71 may block the movement of oxygen ions or oxygen vacancies between the upper interlayer insulating layer 75 and the memory cell MC. The spacer layer 71 may apply compressive stress to the memory cell MC. Other elements in FIG. 2B that are not described may be understood to be substantially the same as the same numbered elements described above with reference to FIG. 2A.

Referring to FIG. 2C, a semiconductor memory device according to an embodiment of the present disclosure may include a lower interconnection line 10 disposed over an underlying layer 5, a memory cell structure MSc over the lower interconnection line 10, and an upper interconnection line 90 over the memory cell structure MSc. The memory cell structure MSc may include a lower contact plug 20, a memory cell MC, a spacer layer 70, a reinforcing layer 72, and an upper contact plug 80. The memory cell MC may include a lower electrode 30, a switching element layer 40, an oxygen reservoir layer 50, and an upper electrode 60.

The spacer layer 70 may conformally cover both sidewalls and a top surface of the memory cell MC. The reinforcing layer 72 may be conformally formed over the spacer layer 70. The reinforcing layer 72 may include a silicon nitride layer. The reinforcing layer 72 may block the movement of oxygen ions or oxygen vacancies between the upper interlayer insulating layer 75 and the memory cell MC. For example, the reinforcing layer 72 may block the movement of oxygen ions or oxygen vacancies between the upper interlayer insulating layer 75 and the spacer layer 70. The reinforcing layer 72 may apply compressive stress to the spacer layer 70 and/or the memory cell MC. Other elements that are not described in FIG. 2C may be understood to be substantially the same as the same numbered elements described above with reference to FIG. 2A.

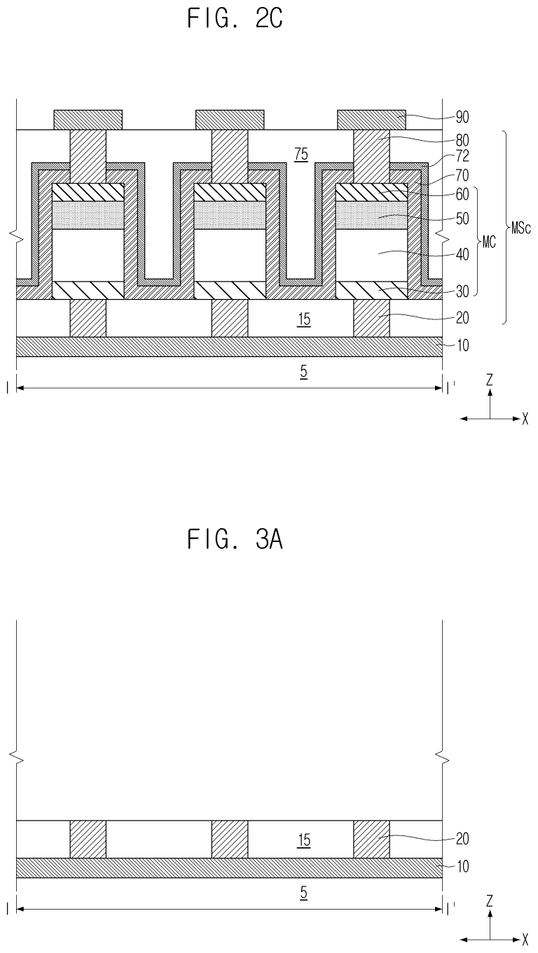

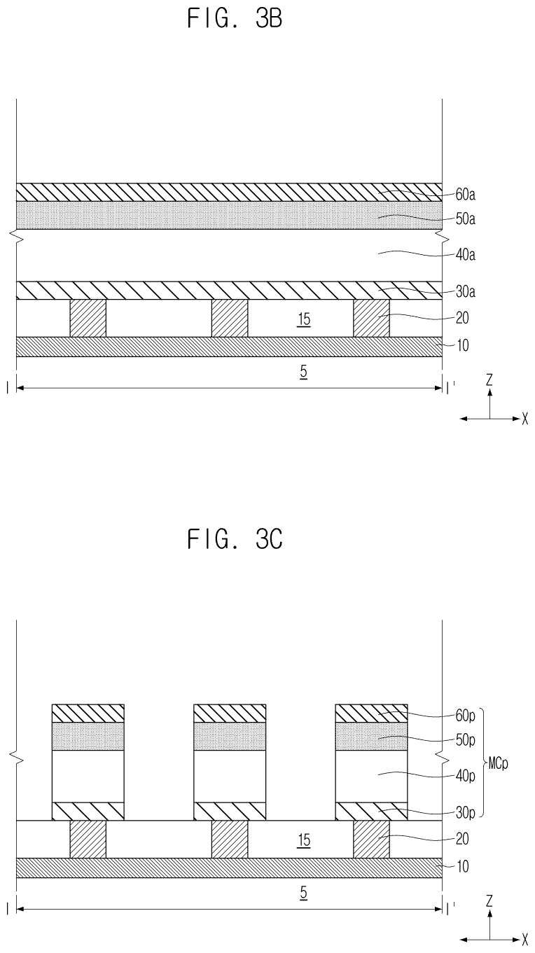

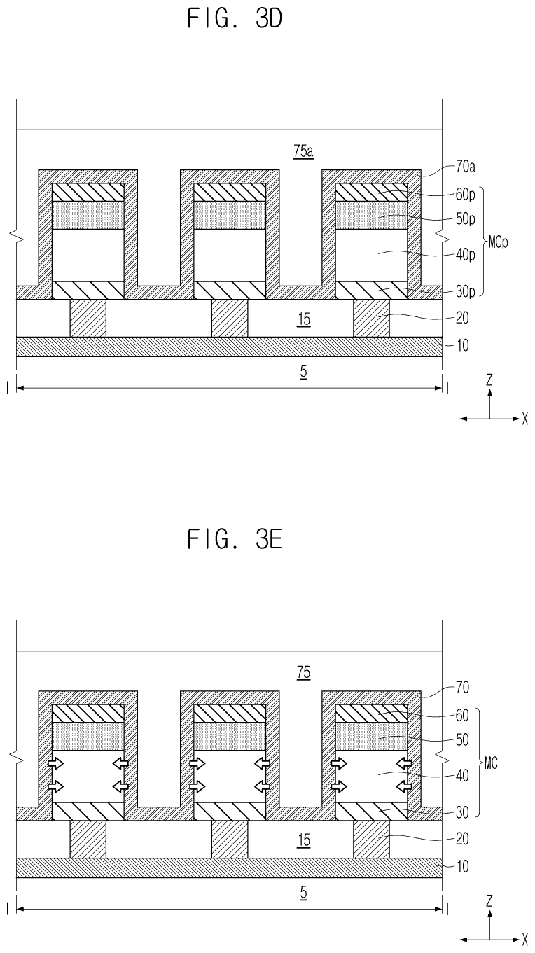

FIGS. 3A to 3E are longitudinal cross-sectional views taken along the line I-I′ of FIG. 1B to illustrate a method of forming a memory cell structure of a semiconductor memory device according to an embodiment of the present disclosure. Referring to FIG. 3A, a method of forming the memory cell structure MSa may include forming an underlying layer 5, forming a lower interconnection line 10 over the underlying layer 5, forming a lower interlayer insulating layer 15 over the lower interconnection line 10, and forming a lower contact plug 20 vertically penetrating the lower interlayer insulating layer 15 and electrically connected to the lower interconnection line 10.

Forming the underlying layer 5 may include forming a silicon oxide-based insulating layer or a silicon nitride-based insulating layer by performing a deposition process.

Forming the lower interconnection line 10 may include performing a deposition process and a patterning process to form a conductive pattern extending in the first horizontal direction X over the underlying layer 5.

Forming the lower interlayer insulating layer 15 may include forming a silicon oxide-based insulating layer or a silicon nitride-based insulating layer by performing a deposition process.

Forming the lower contact plug 20 may include performing a photolithography process, an etching process, and a deposition process to form a lower hole vertically penetrating the lower interlayer insulating layer 15 to expose an upper surface of the lower interconnection line 10, and to fill the lower hole with a conductive material. Forming the lower contact plug 20 may further include performing a planarization process to planarize upper surface of the lower contact plug 20 and the lower interlayer insulating layer 15 to be co-planar.

Referring to FIG. 3B, the method may further include forming a lower electrode material layer 30a over the lower contact plug 20, a switching element material layer 40a over the lower electrode material layer 30a, an oxygen reservoir material layer 50a over the switching element material layer 40a, and an upper electrode material layer 60a over the oxygen reservoir material layer 50a.

Forming the lower electrode material layer 30a may include forming a conductive material layer over the lower contact plug 20 and the lower interlayer insulating layer 15 by performing a deposition process. For example, the lower electrode material layer 30a may include a metal such as tungsten or a metal nitride such as titanium nitride.

Forming the switching element material layer 40a may include forming a metal oxide layer over the lower electrode material layer 30a by performing a deposition process. For example, the switching element material layer 40a may include a hafnium oxide layer.

Forming the oxygen reservoir material layer 50a may include forming a metal oxide layer over the switching element material layer 40a by performing a deposition process. For example, the oxygen reservoir material layer 50a may include at least one of a tantalum layer, a hafnium layer, a zirconium layer, a titanium layer, a tantalum oxide layer, a hafnium oxide layer, a zirconium oxide layer, or a titanium oxide layer.

Forming the upper electrode material layer 60a may include forming a conductive material layer over the oxygen reservoir material layer 50a by performing a deposition process. For example, the upper electrode material layer 60a may include a metal such as tungsten or titanium, or a metal nitride such as titanium nitride.

Referring to FIG. 3C, the method may further include forming a preliminary memory cell MCp by patterning the upper electrode material layer 60a, the oxygen reservoir material layer 50a, the switching element material layer 40a, and the lower electrode material layer 30a. Forming the preliminary memory cell MCp may include forming a mask pattern (not shown) over the upper electrode material layer 60a and performing an etching process to selective etch the upper electrode material layer 60a, the oxygen reservoir material layer 50a, the switching element material layer 40a, and the lower electrode material layer 30a using the mask pattern as an etching mask. The preliminary memory cell MCp may include a preliminary lower electrode 30p, a preliminary switching element layer 40p, a preliminary oxygen reservoir layer 50p, and a preliminary upper electrode 60p.

Referring to FIG. 3D, the method may include conformally forming a straining layer 70a covering the lower interlayer insulating layer 15 and the preliminary memory cell MCp, and forming a gap-fill layer 75a over the straining layer 70a. The gap-fill layer 75a may be formed over the straining layer 70a to fill spaces between the preliminary memory cells MCp.

The straining layer 70a may include a stress generating material layer. For example, the straining layer 70a may include a zinc sulfide layer having cubic phase crystal structures. The straining layer 70a may be formed by performing a deposition process or a wet precipitation process.

Referring to FIG. 3E, the method may include changing the straining layer 70a into a spacer layer 70 by performing a phase change process. The phase change process may include a straining process. The phase change process may include a low temperature thermal treatment process. The low temperature thermal treatment process may include heating the straining layer 70a for about 10 minutes to 2 hours at a temperature of about 300° C. or less, specifically 250° C. or less. In some embodiments, the low temperature thermal treatment process may include heating the straining layer 70a for about 10 minutes to 2 hours at a temperature of about 200° C. or less. The spacer layer 70 may include a zinc sulfide layer having hexagonal phase crystal structures. In an embodiment, the spacer layer 70 may include both the cubic phase crystal structures and the hexagonal phase crystal structures. Zinc (Zn) atoms in the cubic phase crystal structure may be spaced apart from each other at a distance of about 0.538 nm, and zinc atoms in the hexagonal phase crystal structure may be spaced apart from each other at a distance of about 0.638 nm. Therefore, the straining layer 70a may apply compressive stress to the preliminary memory cell MCp during and after being phase-changed to the spacer layer 70. The preliminary memory cell MCp subjected to the compression stress may be modified into the memory cell MC. The gap-fill layer 75a may be changed into an upper interlayer insulating layer 75.

A magnitude of the compression stress may be set depending on an execution time of the phase change process. For example, if the phase change process takes longer time, the proportion of hexagonal phase crystal structures in the spacer layer 70 may increase, thus the compressive stress applied by the preliminary memory cell MCp may increase.

Under compression stress, a distance between atoms of the elements of the preliminary memory cell MCp decreases, forming a memory cell MC. Travel distances of oxygen atoms, oxygen ions, or oxygen vacancies in the switching element layer 40 can be reduced and a diffusion barrier can be increased. Permission rate of movement and diffusion of the oxygen atoms or the oxygen ions in the switching element layer 40 can be lowered. Within the switching element layer 40, an extinction time of the formed filaments can be lengthened, and retention characteristics of the filaments can be improved. Data retention properties of the switching element layer 40 can be improved.

Since the zinc sulfide layer, that is, a material layer containing no oxygen and/or nitrogen, is used as the spacer layer 70, a portion of the switching element layer 40 can be prevented from being oxidized and/or nitrided. That is, at least a portion of the switching element layer 40 can be prevented from being lost due to oxidation or nitridation. Furthermore, by performing the phase change process under low-temperature conditions, material changes such as phase change and crystal change of the switching element layer 40 and oxygen reservoir layer 50 can be minimized.

Hereinafter, referring to FIG. 2A as an example, the method may further include forming an upper contact plug 80 and an upper interconnection line 90. Forming the upper contact plug 80 may include performing a photolithography process and an etching process to form an upper hole vertically penetrating the upper interlayer insulating layer 75 and the spacer layer 70 to expose an upper surface of the upper electrode 60, performing a deposition process to fill the upper hole with a conductive material, and performing a planarization process to planarize upper surfaces of the upper contact plug 80 and upper interlayer insulating layer 75. Forming the upper interconnection line 90 may include performing a deposition process and a patterning process to form a conductive pattern extending in the second horizontal direction Y over the upper contact plug 80 and the upper interlayer insulating layer 75.

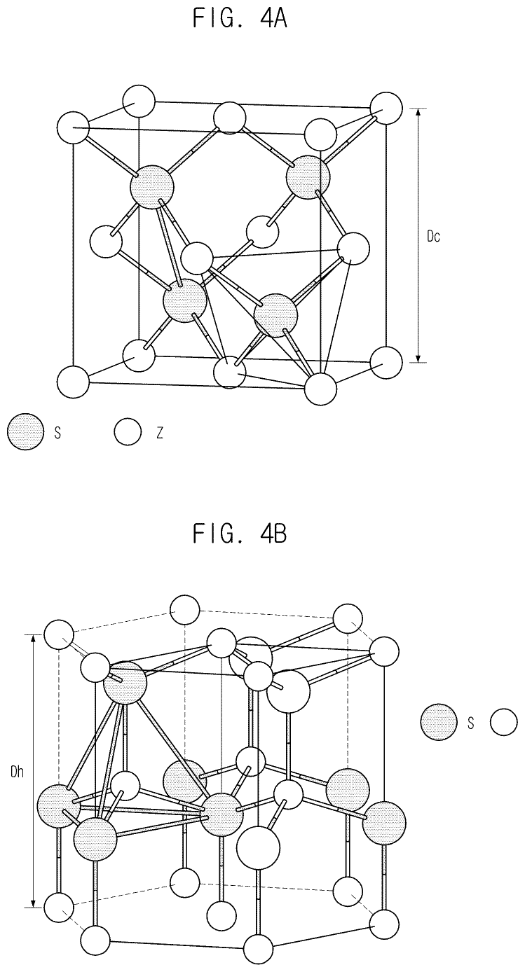

FIG. 4A illustrates a cubic phase crystal structure of zinc sulfide, and FIG. 4B illustrates a hexagonal phase crystal structure of zinc sulfide according to an embodiment of the present disclosure. Referring to FIGS. 4A and 4B, a spacing distance Dc between zinc atoms Z in the cubic phase crystal structure may be about 0.538 nm, and a spacing distance Dh between zinc atoms Z in the hexagonal phase crystal structure may be about 0.638 nm. Therefore, when the straining layer 70a having the cubic phase crystal structures is phase-changed into the spacer layer 70 having hexagonal phase crystal structures, compressive stress may be applied to the memory cell MC.

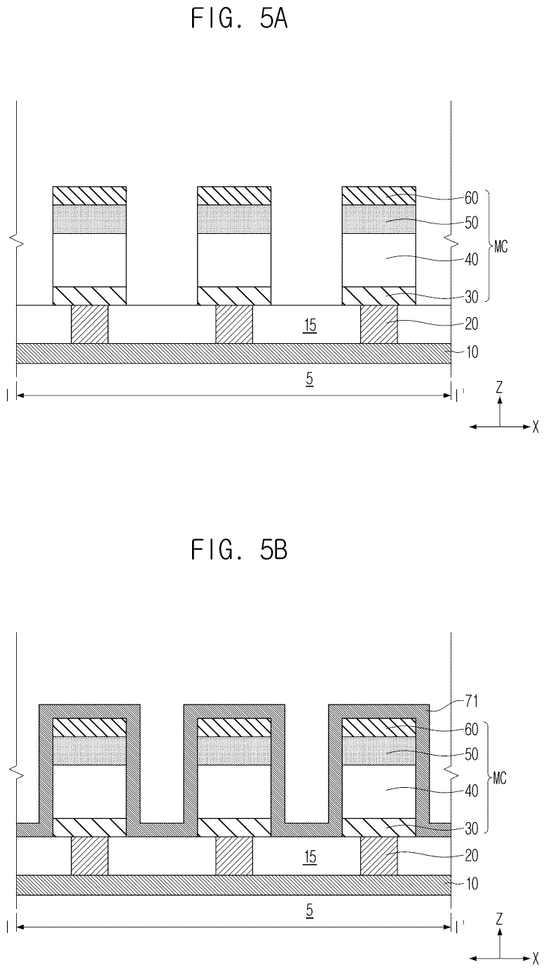

FIGS. 5A and 5B are longitudinal cross-sectional views taken along line I-I′ of FIG. 1B to illustrate a method of forming a memory cell structure MSb of a semiconductor memory device according to an embodiment of the present disclosure. Referring to FIG. 5A, a method of forming the memory cell structure MSb may include performing the processes described with reference to FIGS. 3A to 3D, performing a modifying process to apply a compression stress to the preliminary memory cell MCp, and removing the gap-fill layer 75a and the straining layer 70a.

Referring to FIG. 5B, the method may further include conformally forming a spacer layer 71. The spacer layer 71 may include an inorganic material layer that does not contain oxygen atoms. For example, the spacer layer 71 may include an insulating layer based on silicon nitride. Thereafter, referring to FIG. 2B, the method may further include forming an upper interlayer insulating layer 75, an upper contact plug 80, and an upper interconnection line 90.

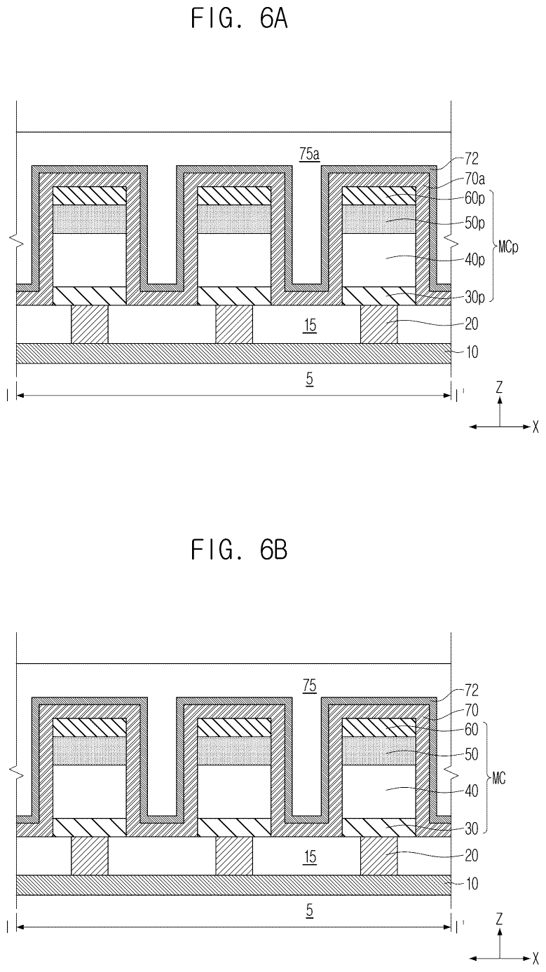

FIGS. 6A and 6B are longitudinal cross-sectional views taken along line I-I′ of FIG. 1B to illustrate a method of forming a memory cell structure of a semiconductor memory device according to another embodiment of the present disclosure. Referring to FIG. 6A, a method of forming the memory cell structure MSc may include performing the processes described with reference to FIGS. 3A to 3C, forming a straining layer 70a covering the lower interlayer insulating layer 15 and the preliminary memory cell MCp, forming a reinforcing layer 72 over the straining layer 70a, and forming a gap-fill layer 75a. The straining layer 70a may have the cubic phase crystal structures. The reinforcing layer 72 may include a denser and more solid insulating layer than the gap-fill layer 75a. For example, the reinforcing layer 72 may include a silicon nitride layer.

Referring to FIG. 6B, the method may include performing a phase change process to phase-change the straining layer 70a into a spacer layer 70. The reinforcing layer 72 may reinforce compressive stress applied to the switching element layer 40 while the straining layer 70a being phase-changed. In addition, the reinforcing layer 72 may block moving of oxygen ions or oxygen vacancies between the gap-fill layer 75a and the preliminary memory cell MCp or between the gap-fill layer 75a and the straining layer 70a in the phase change process.

Thereafter, the method may further include forming an upper contact plug 80 and an upper interconnection line 90 with reference to FIG. 2C. The upper contact plug 80 may penetrate both the reinforcing layer 72 and the spacer layer 70 over the upper portion of the memory cell MC.

According to the embodiments of the present disclosure, data retention of a resistive semiconductor memory device may be improved.

While the present disclosure has been described with respect to some specific embodiments, it will be apparent to those skilled in the art that various changes and modifications may be made without departing from the spirit and scope of the disclosure as defined in the following claims.

What is claimed is:

1. A method of manufacturing a semiconductor device comprising:
forming a lower interconnection line;
forming a lower interlayer insulating layer over the lower interconnection line;
forming a lower contact plug vertically penetrating the lower interlayer insulating layer to be electrically connected to the lower interconnection line;
forming a memory cell over the lower contact plug;
forming a straining layer surrounding the memory cell;
performing a phase change process to phase-change the straining layer into a spacer layer;
forming an upper contact plug electrically connected to an upper portion of the memory cell; and
forming an upper interconnection line over the upper contact plug,
wherein the spacer layer includes hexagonal phase crystal structures.

2. The method of claim 1,
wherein the phase change process includes heating the straining layer at a temperature of 300° C. or less.

3. The method of claim 1,
wherein the spacer layer further includes cubic phase crystal structures.

4. The method of claim 1,
wherein forming the memory cell includes:
forming a lower electrode material layer;
forming a switching element material layer over the lower electrode material layer,
forming an oxygen reservoir material layer over the switching element material layer,
forming an upper electrode material layer over the oxygen reservoir material layer, and
patterning the upper electrode material layer, the oxygen reservoir material layer, the switching element material layer, and the lower electrode material layer to form an upper electrode, an oxygen reservoir layer, a switching element layer, and a lower electrode.

5. The method of claim 1, further comprising:
conformally forming a silicon nitride layer over the straining layer.

6. The method of claim 1, further comprising:
removing the spacer layer, and
forming a silicon nitride layer conformally surrounding the memory cell.

7. The method of claim 1,
wherein the straining layer includes cubic phase crystal structures.

8. A method of manufacturing a semiconductor device comprising:
forming a switching element layer;
forming a first material layer surrounding side surfaces of the switching element layer; and
performing a phase change process to phase-change the first material layer into a second material layer,
wherein the first material layer includes cubic crystal structures,
wherein the second material layer includes hexagonal phase crystal structures.

9. The method of claim 8,
wherein the phase change process includes heating the first material layer at a temperature of 250° C. or less.

10. The method of claim 8, wherein the first material layer contains zinc sulfide.

11. The method of claim 8,
wherein the switching element layer includes at least one of a metal-insulator transition (MIT) material layer, a mixed ion-electron conductor (MIEC) material layer, an OTS (Ovonic Threshold Switching) material layer, or a transition metal oxide.

12. The method of claim 8, further comprising:
forming an oxygen reservoir layer over the switching element layer,
wherein the first material layer further surrounds side surfaces of the oxygen reservoir layer.

13. The method of claim 8, further comprising:
forming a silicon nitride layer over the first material layer before performing the phase change process.
